(19) United States
(12) Patent Application Publication
(10) Pub. No.: US 2025/0089400 A1
(43) Pub. Date: Mar. 13, 2025

(54) LIGHT EMITTING DEVICE

(71) Applicant: EPISTAR CORPORATION, Hsinchu (TW)

(72) Inventors: Hao-Chun LIANG, Hsinchu (TW); Yi-Shan TSAI, Hsinchu (TW); Wei-Shan YEOH, Hsinchu (TW); Yao-Ning CHAN, Hsinchu (TW); Hsuan-Le LIN, Hsinchu (TW); Jiong-Chaso SU, Hsinchu (TW); Shih-Chang LEE, Hsinchu (TW); Chang-Da TSAI, Hsinchu (TW)

(21) Appl. No.: 18/243,985

(22) Filed: Sep. 8, 2023

(51) Int. Cl. H01L 33/06; H01L 33/10; H01L 33/30

(52) U.S. Cl. CPC H10H 20/812; H10H 20/814; H10H 20/824

(57) ABSTRACT

A semiconductor device, including a base and a semiconductor stack. The semiconductor stack includes a first semiconductor structure located on the base, a second semiconductor structure located on the first semiconductor structure, and an active structure located between the first semiconductor structure and the second semiconductor structure. The active structure includes two confinement layers and a well layer located between the two confinement layers. One of the confinement layers includes Alₓ₁Ga₁₋ₓ₁As, and x1 is equal to or larger than 0.25 and equal to or smaller than 0.4. The well layer includes Inₓ₂Ga₁₋ₓ₂As, and x2 is equal to or larger than 0.25 and equal to or smaller than 0.3. The one of the confinement layers and the well layer respectively have a first thickness in a range of 200 nm to 400 nm and a second thickness in a range of 3 nm to 6 nm.

### TECHNICAL FIELD

The disclosure relates to a semiconductor device, and particularly to a semiconductor device suitable for coupling with a detector.

### DESCRIPTION OF BACKGROUND ART

Semiconductor devices had been extensively adopted in daily life. III-V compound semiconductor, such as GaP, InGaAs or GaN, has favorable optoelectronic characteristics for integrated circuit (IC), light-emitting diode (LED), laser diode, or photodetector. For LED, the conventional structure includes a p-type semiconductor structure, an active structure and an n-type semiconductor structure that are stacked together, and the p-type semiconductor structure and the n-type semiconductor structure are formed by process design (e.g., doping process). Under an external electrical power supply, the n-type semiconductor structure and the p-type semiconductor structure provide electrons and holes respectively to be recombined in the active structure and to be further converted into light.

LED has many advantages, such as low energy consumption, small size, fast response speed and long working life, and is widely used in the fields of display, lighting and communication. In the field of optical communication, a characteristic of precisely output power control is desirable for LED.

### SUMMARY OF THE DISCLOSURE

The present disclosure provides a semiconductor device, including a base and a semiconductor stack. The semiconductor stack includes a first semiconductor structure located on the base, a second semiconductor structure located on the first semiconductor structure, and an active structure located between the first semiconductor structure and the second semiconductor structure. The active structure includes two confinement layers and a well layer located between the two confinement layers. One of the confinement layers includes Alₓ₁Ga₁₋ₓ₁As, and x1 is equal to or larger than 0.25 and equal to or smaller than 0.4. The well layer includes Inₓ₂Ga₁₋ₓ₂As, and x2 is equal to or larger than 0.25 and equal to or smaller than 0.3. The one of the confinement layers and the well layer respectively have a first thickness in a range of 200 nm to 400 nm and a second thickness in a range of 3 nm to 6 nm.

The present disclosure also provides a transmission module. The transmission module includes a semiconductor device and a light receiver. The semiconductor device emits a signal light with a peak wavelength at an input current. The light receiver receives the signal light to output an output current. The output current is proportional to the input current.

### BRIEF DESCRIPTION OF THE DRAWINGS

The foregoing aspects and many of the attendant advantages of the present disclosure will become more readily appreciated as the same becomes better understood by reference to the following detailed description, when taken in conjunction with the accompanying drawings, wherein:

FIG. 1A shows a top view of a semiconductor device disclosed in accordance with one embodiment of the present disclosure;

FIG. 1B shows a cross-sectional view of the semiconductor device along A-A′ line in FIG. 1A:

FIG. 1C shows a cross-sectional view of a semiconductor stack in accordance with one embodiment of the present disclosure:

FIG. 1D shows a cross-sectional view of a semiconductor stack in accordance with one embodiment of the present disclosure:

FIG. 2 shows a graph of input current versus deviation coefficient for different active structures:

FIG. 3 shows a graph of input current versus peak wavelength for different active structures:

FIG. 4A shows a top view of a semiconductor device in accordance with one embodiment of the present disclosure;

FIG. 4B shows a cross-sectional view of the semiconductor device along B-B′ line in FIG. 4A:

FIG. 4C shows a cross-sectional view of a semiconductor device in accordance with one embodiment of the present disclosure;

FIG. 5 shows a schematic view of a transmission module in accordance with one embodiment of the present disclosure.

### DETAILED DESCRIPTION OF PREFERRED EMBODIMENTS

Exemplary embodiments of the present disclosure will be described in detail with reference to the accompanying drawings hereafter. The following embodiments are given by way of illustration with Cartesian Coordinates (X, Y, Z axes) to help those skilled in the art fully understand the spirit of the present disclosure. Hence, it should be noted that the present disclosure is not limited to the embodiments herein and can be realized in various forms. Further, the drawings are not precise scale and components may be exaggerated in view of width, height, length, etc. Herein, the similar or identical reference numerals will denote the similar or identical components throughout the drawings. In the embodiments of the present disclosure, if not described otherwise, the term “horizontal” means any value or vector along X-axis, Y-axis or on X-Y plane, while the term “vertical” means any value or vector along Z-axis. The term “corresponding” may be used to describe different elements are overlapped horizontally (on X-Y plane).

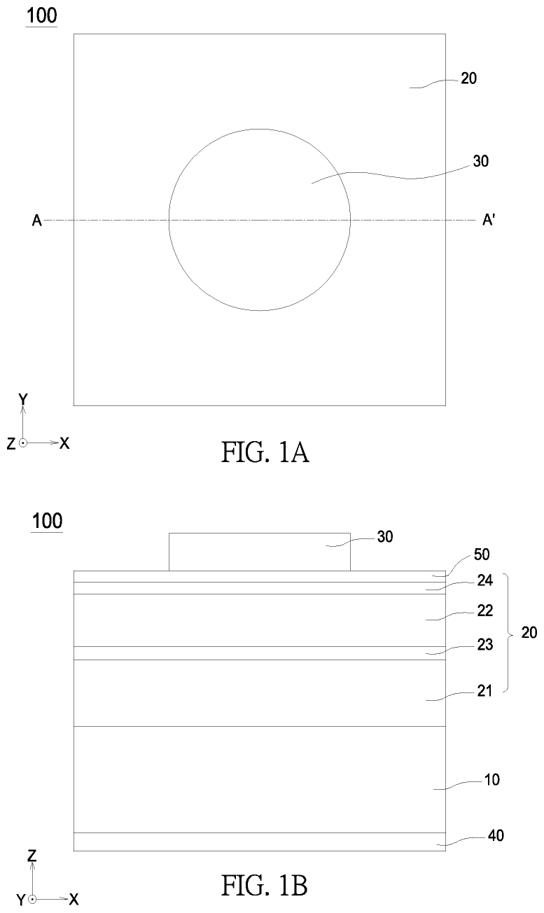

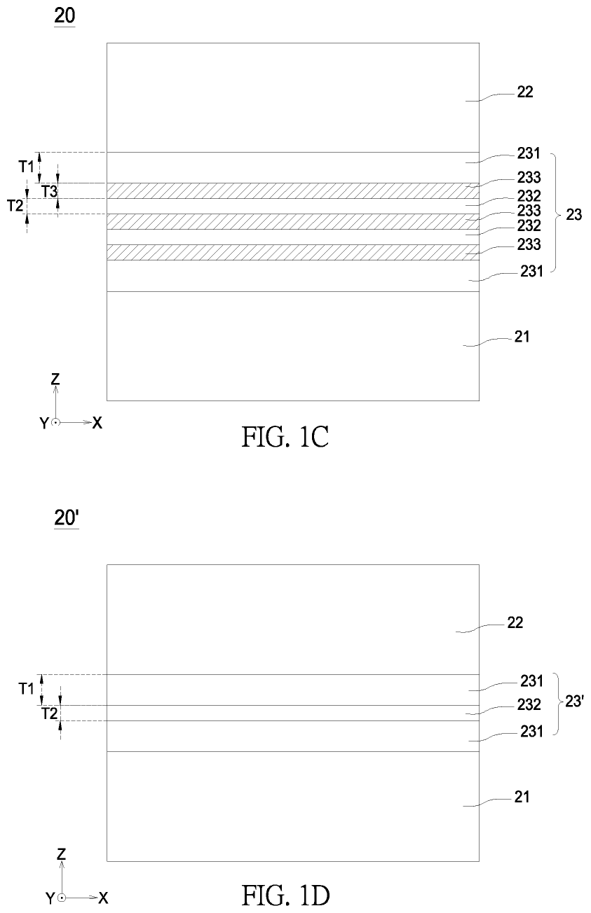

FIG. 1A shows a top view of a semiconductor device 100 in one embodiment in accordance with the present disclosure, and FIG. 1B is a cross-sectional view of the semiconductor device 100 along A-A′ line of FIG. 1A. According to FIGS. 1A and 1B, the semiconductor device 100 includes a base 10, a semiconductor stack 20 located on the base 10, a first electrode structure 30 disposed on the semiconductor stack 20, and a second electrode structure 40 disposed on one side of the base 10 away from the semiconductor stack 20.

The base 10 may directly or indirectly connect to the semiconductor stack 20, and provides mechanic strength to support the semiconductor stack 20. The base 10 can be a growth substrate or a bonding substrate. When the base 10 is a growth substrate, the semiconductor stack 20 is grown on the base 10 through metal-organic chemical vapor deposition (MOCVD), molecular beam epitaxy (MBE) or hydride vapor phase epitaxy (HVPE). When the base 10 is a bonding substrate, the semiconductor stack 20 is grown on another growth substrate, and the another growth substrate can be optionally removed and the semiconductor stack 20 can be further bonded to the base by substrate transfer technique.

The semiconductor stack 20 includes a first semiconductor structure 21 located on the base 10, a second semiconductor structure 22 located on the first 10 semiconductor structure 21 and an active structure 23 located between the first semiconductor structure 21 and the second semiconductor structure 22. The first electrode structure 30 is disposed on the second semiconductor structure 22.

The first semiconductor structure 21 and the second semiconductor structure 22 have opposite conducting type. More specifically, the first semiconductor structure 21 and the second semiconductor structure 22 may be a p-type semiconductor structure and an n-type semiconductor structure (or an n-type semiconductor structure and a p-type semiconductor structure). In the embodiment, the semiconductor device 100 is a semiconductor light emitting device and the first semiconductor structure 21 and the second semiconductor structure 22 respectively provide holes and electrons (or electrons and holes) which are recombined within the active structure 23 to emit light with a peak wavelength. The light passes through the second semiconductor structure 22 and emits outward. In one embodiment, an upper surface of the second semiconductor structure 22 is a light extraction surface of the semiconductor device 100, and the upper surface of the second semiconductor structure 22 can be roughing to improve a light extraction efficiency of the semiconductor device 100.

The active structure 23 can include multiple quantum wells structure (MQW). The p-type semiconductor structure may include a p-type doping element, such as C, Zn, Be or Mg. The n-type semiconductor structure may include an n-type doping element, such as Si, Ge, Sn, Se or Te. In some embodiments, the first semiconductor structure 21 and the second semiconductor structure 22 may have a doping concentration in a range between 5×10¹⁶/cm³ to 1×10²⁰/cm³. The first semiconductor structure 21 and/or the second semiconductor structure 22 may be a single layer structure or multi-layer structure.

The light emitted by the active structure 23 may include visible light and/or invisible light. The peak wavelength of the light is determined by the material of the active structure 23. For example, when the material of the active structure 23 includes InGaN series, for example, it can emit blue light or deep blue light with a peak wavelength of 400 nm to 490 nm, or green light with a peak wavelength of 490 nm to 550 nm, or red light with a peak wavelength of 560 nm to 650 nm; when the material of the active structure 23 includes AlGaN series, for example, it can emit ultraviolet light with a peak wavelength of 250 nm to 400 nm; when the material of the active structure 23 includes InGaAs series, InGaAsP series, AlGaAs series or AlGaInAs series, for example, it can emit infrared light with a peak wavelength of 700 nm to 1700 nm: when the material of the active structure 23 includes InGaP series or AlGalnP series, for example, it can emit red light with a peak wavelength of 610 nm to 700 nm, or yellow light with a peak wavelength of 530 nm to 600 nm.

FIG. 1C shows a schematic view of the semiconductor stack 20 in accordance with one embodiment of the present disclosure. The semiconductor stack 20 includes the active structure 23 with two confinement layers 231 and a well layer 232 located between the two confinement layers 231. In some embodiments, the active structure 23 may include multiple well layers 232, and quantity of the multiple well layers 232 is equal to or less than 2, such as 2 or 1. In some embodiments, the active structure 23 may optionally include a plurality of barrier layers 233 disposed between the well layer 232 and one of the two confinement layers 231 or between of the adjacent well layers 232. Referring to FIG. 1C, in this embodiment, the active structure 23 includes two confinement layers 231, two well layers 232 and three barrier layers 233. The two well layers 232 and the three barrier layers 233 are disposed between the two confinement layers 231 and alternately stacked with each other. In this embodiment, the well layers 232 do not contact any of the two confinement layers 231. In other embodiments, the well layers 232 may contact one of the two confinement layers 231 directly.

The two confinement layers 231 may have same or different materials. In some embodiments of the present disclosure, one of two the confinement layers 231 may include Alₓ₁Ga₁₋ₓ₁As, and one of the well layers 232 may include Inₓ₂Ga₁₋ₓ₂As, and one of the barrier layers 233 may include Alₓ₃Ga₁₋ₓ₃As_{y}P_{1-y}, and 0≤×1, x2, x3, y≤1. In some embodiments, x1 is equal to or larger than 0.25 and equal to or smaller than 0.4. In some embodiments, x2 is equal to or larger than 0.25 and equal to or smaller than 0.3. In some embodiments, x3 is equal to or larger than 0.25 and equal to or smaller than 0.35, and y is equal to or larger than 0.15 and equal to or smaller than 0.25. In some embodiments, the active structure 23 may emit infrared light with the peak wavelength of 850 nm to 1150 nm.

One of the two confinement layers 231 has a first thickness TI, and the thicknesses of the two confinement layers 231 may be the same or different. One of the well layers 232 has a second thickness T2, and the thicknesses of the well layers 232 may be the same or different. One of the barrier layers 233 has a third thickness T3, and the thicknesses of the barrier layers 233 may be the same or different. In some embodiments, the first thickness T1 is in a range of 200 nm to 400 nm. In some embodiments, the second thickness T2 is in a range of 3 nm to 6 nm. In some embodiments, the third thickness T3 is in a range of 3 nm to 6 nm.

FIG. 1D shows a schematic view of a semiconductor stack 20′in accordance with one embodiment of the present disclosure. In this embodiment, the semiconductor stack 20′ includes the active structure 23′ with only one well layer 232 and without having the barrier layer 233. As shown in FIG. 1D, the well layer 232 is directly sandwiched by the two confinement layers 231. Thus, the active structure 23′ has a simpler structure than the active structure 23 of FIG. 1C to reduce a total thickness of the semiconductor stack 20.

Referring to FIG. 1B, in some embodiments, the semiconductor stack 20 may optionally include a first contact layer 24 located between the second semiconductor structure 22 and the first electrode structure 30. The first contact layer 24 may partially or entirely cover the upper surface of the second semiconductor structure 22. In this embodiment, the first contact layer 24 entirely covers the upper surface of the second semiconductor structure 22. The first contact layer 24 forms a low resistance interface between the second semiconductor structure 22 and the first electrode structure 30, so as to reduce a forward voltage of the semiconductor device 100. The first contact layer 24 can have the same conducting type as that of the second semiconductor structure 22. The first contact layer 24 may have a doping concentration higher than that of the second semiconductor structure 22 to form a better electrical contact with the first electrode structure 30. In some embodiments, the doping concentration of the first contact layer 24 is in a range of 1×10¹⁸/cm³ to 1×10²⁰/cm³. In some embodiments, the first contact layer 24 may have a thickness in a range of 50 nm to 100 nm.

Referring to FIG. 1B, the semiconductor device 100 may optionally include a first conductive structure 50 disposed between the semiconductor stack 20 and the first electrode structure 30. The first conductive structure 50 may facilitate lateral current spreading (along X-axis and/or Y-axis) for currents flowing in or out the semiconductor stack 20, so as to improve light emitting uniformity and intensity of the semiconductor device 100. The first conductive structure 50 may partially or entirely disposed on the first contact layer 24 (or the second semiconductor structure 22). In this embodiment, the first conductive structure 50 entirely covers the first contact layer 24. Besides, the first conductive structure 50 may be transparent for the light emitted from the active structure 23. In some embodiments, the first conductive structure 50 has a transmittance over 80% for the light emitted from the active structure 23. Further, the first conductive structure 50 may have a thickness in a range of 250 nm to 350 nm.

The semiconductor device 100 of the present disclosure can be operated at an input current (or voltage) to emit the light and output a power, and the power and/or the peak wavelength of the light vary with the input current (or voltage). Specifically, the semiconductor device 100 outputs the power in a form of the light. The amount of the light increases with the input current, and the power increases with the input current as well. In one embodiment, the semiconductor device 100 is operated at a first current I1, a second current I2 and a third current I3, and respectively outputs a first power P1, a second power P2 and a third power P3. The first current I1, the second current I2 and the third current I3 are different from each other, and the first power P1, the second power P2 and the third power P3 are different from each other. The second current I2 is smaller than the first current I1, and the second power P2 is smaller than the first power P1. Similarly, the third current I3 is larger than the first current I1, and the third power P3 is larger than the first power P1.

A current ratio R is defined as the ratio of an operated current to a reference current. In this embodiment, the first current I1 is the reference current, and the second current I2 and the third current I3 are the operated currents. The second current I2 to the first current I1 is defined as a first current ratio RI, and the third current I3 to the first current I1 is defined as a second current ratio R2. The first current I1, the second current I2 and the third current I3 are in a range of 0.1 mA to 50 mA. For example, the first current I1, the second current I2 or the third current I3 can be 0.1 mA, 0.5mA, 1 mA, 5 mA, 10 mA, 25 mA or 50 mA. Likewise, a power ratio is defined as the ratio of a power where the semiconductor device 100 is operated at the operated current to a power where the semiconductor device 100 is operated at the reference current. In this embodiment, a first power ratio is defined as the second power P2 to the first power P1, and a second power ratio is defined as the third power P3 to the first power P1.

In some embodiments, the semiconductor device 100 has a deviation coefficient which is defined as the power ratio divided by the current ratio. As described above, the first current I1 is the reference current, and the second current I2 and the third current I3 are the operated currents, therefore a first deviation coefficient D1 is the first power ratio divided by the first current ratio R1, that is D1=(P2/P1)/RI when the semiconductor device 100 is operated at the second current I2. Similarly, a second deviation coefficient D2 is the second power ratio divided by the second current ratio R2, that is D2=(P3/P1)/R2 when the semiconductor device 100 is operated at the third current I3. The deviation coefficient represents a consistency between the power ratio and the current ratio, i.e., the degree of a variation of the power is consistent with a variation of the input current. In some embodiment, the first deviation coefficient D1 and the second deviation coefficient D2 are in a range of 0.8 and 1.2, such as in a range of 0.85 and 1.1, for being suitable for applying in signal transmission.

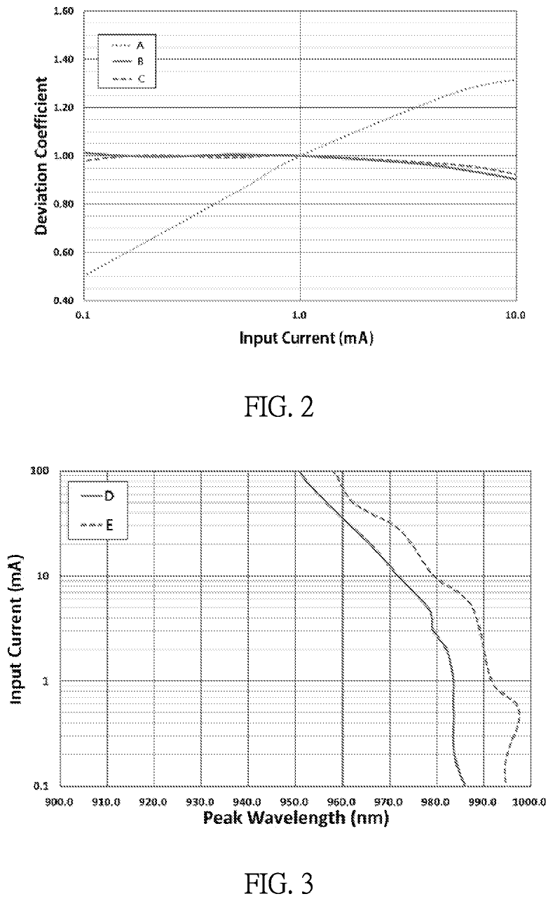

FIG. 2 is a graph of input current versus deviation coefficient, and shows the deviation coefficient at the input current between 0.1 mA to 10 mA. In FIG. 2, curve A represents a semiconductor device which has a similar structure with the semiconductor device 100 of the present disclosure, except for the active structure having 4 well layers. Curve B represents the semiconductor device 100 having the active structure 23 with 2 well layer 232, and curve C represents a semiconductor device 100′ which is similar to the semiconductor device 100 and has the active structure 23′ with 1 well layer 232. In the embodiment of FIG.2 the first current I1 (the reference current) is 1 mA, and the second current I2 and the third current I3 (the operated currents) are respectively smaller than 1 mA and larger than 1 mA.

In FIG. 2, the deviation coefficient of curve A gradually increases with the input current. On the contrary, the deviation coefficients of curve B and curve C are more stable. More specifically, the deviation coefficients of curve B and curve C become flatter than that of curve A, which means the consistencies between the power ratio and the current ratio in curve B and curve C are better than in curve A. In the range of 0.1 mA to 10 mA, the deviation coefficients of curve B and curve C are within 0.9 to 1.05.

As shown in FIG. 2, for both the curve B and curve C, the deviation coefficient at the operated current smaller than the reference current is more stable than that at the operated current larger than the reference current. More specifically, the first deviation coefficient D1 varies between 0.98 to 1.02 at the second current I2 smaller than the first current I1, while the second deviation coefficient D2 drops from 0.9 to 1 at the third current I3 larger than first current I1. That is to say, when the semiconductor device 100 and the semiconductor device 100′ are operated at the third current I3, an increase of the power is not as much as an increase of the input current.

Referring to FIG. 3, the peak wavelength of the light decreases as the input current increases. More specifically, the semiconductor device 100 of the present disclosure emits a first light L1 having a first peak wavelength W1 when operated at the first current I1, and emits a second light L2 having a second peak wavelength W2 when operated at the second current I2, and emits a third light L3 having a third peak wavelength W3 when operated at the third current I3. The first peak wavelength W1, the second peak wavelength W2 and the third peak wavelength W3 may be different from each other. In this embodiment, the second current I2 is smaller than the first current I1, and the second peak wavelength W2 is larger than the first peak wavelength W1. The third current I3 is larger than the first current I1, and the third peak wavelength W3 is smaller than the first peak wavelength W1.

FIG. 3 is a graph of input current versus peak wavelength of the present disclosure. Curve D represents the semiconductor device 100 having the active structure 23 with 2 well layers 232, and curve E represents the semiconductor device 100′ having the active structure 23′ with 1 well layer 232. As shown in FIG. 3, as the input current increases from 0.1 mA to 100 mA, the peak wavelength of curve D decreases from 986 nm to 950 nm and the peak wavelength of curve E decreases from 995 nm to 958 nm. According to FIG. 3, the peak wavelength of the light emitted from the active structure 23 and the active structure 23′ show blue shifting behavior.

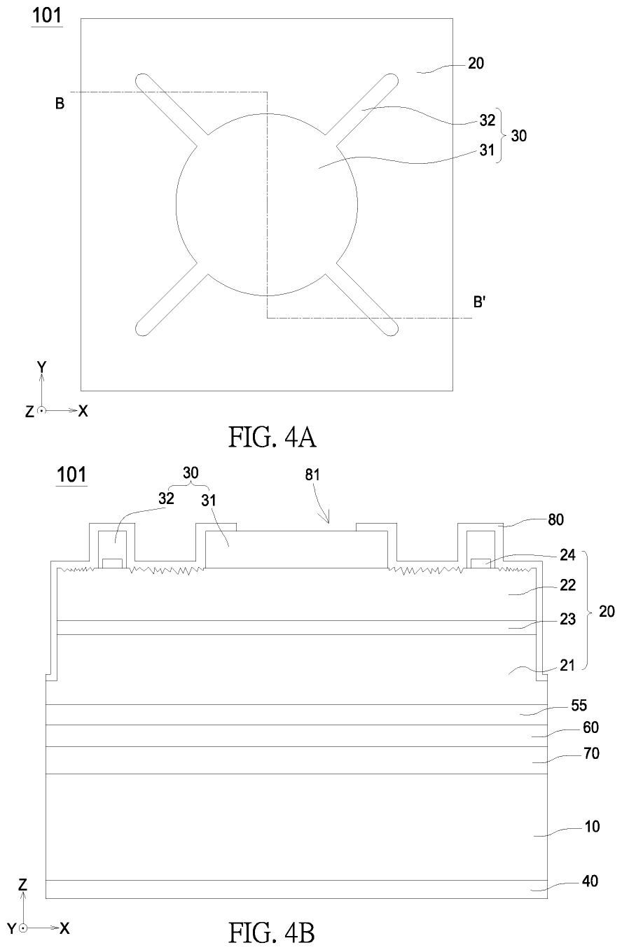

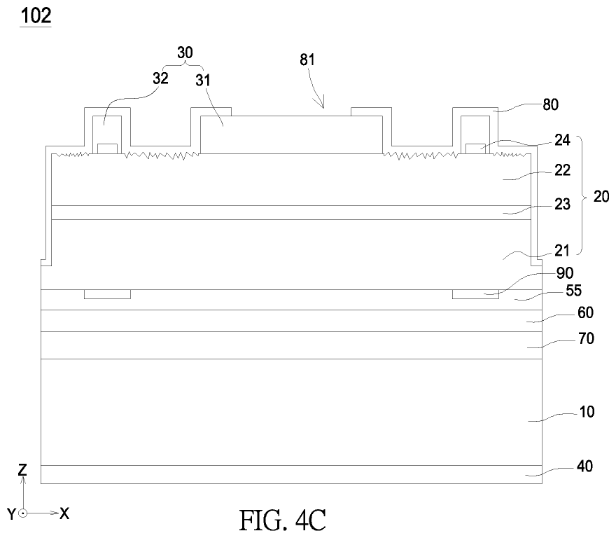

FIG. 4A shows a top view of a semiconductor device 101 in another embodiment in accordance with the present disclosure, and FIG. 4B is a cross-sectional view of the semiconductor device 101 along B-B′ line of FIG. 4A. The semiconductor device 101 is similar to the semiconductor device 100, and includes the base 10, the semiconductor stack 20, the first electrode structure 30 and the second electrode structure 40 described above. In this embodiment, the base 10 is a bonding substrate. Referring to FIG. 4A, the first electrode structure 30 includes a pad portion

31 and an extending portion 32 extending from the pad portion 31. The first electrode structure 30 may have a plurality extending portions 32 to improve current spreading. In this embodiment, the first electrode structure 30 includes four extending portions 32 which are separated from each other and extending toward four corners of the semiconductor stack 20.

Referring to FIG. 4B, the first contact layer 24 of the semiconductor device 101 partially covers the second semiconductor structure 22. The first contact layer 24 may be patterned to correspond to the first electrode structure 30, so as to reduce light absorption. More specifically, the first contact layer 24 may be disposed corresponding to the pad portion 31, the extending portion 32 or both. In this embodiment, the first contact layer 24 is disposed under the extending portions 32 without overlapping with the pad portion 31 in a vertical direction (along Z-axis). Thus, currents flow in or out the semiconductor stack 20 through the extending portions 32 instead of the pad portion 31, and a light blocking effect of the pad portion 31 can be prevented.

As shown in FIG. 4B, the semiconductor device 101 further includes a reflecting structure 60 disposed between the semiconductor stack 20 and the base 10, and a bonding structure 70 disposed between the base 10 and the reflecting structure 60 to bond the base 10 and the reflecting structure 60 together. The reflecting structure 60 reflects the light emitted by the active structure 23 towards the second semiconductor structure 22 to emit outwards, so a light extraction efficiency of the semiconductor device 101 can be improved. In some embodiments, the reflecting structure 60 has high reflectivity for the light emitted by the active structure 23, such as over 80%. The reflecting structure 60 may be a single layer or multi-layer structures. The reflecting structure 60 and the bonding structure 70 are conductive so that the second electrode structure 40 can form electrical connection with the first semiconductor structure 21.

As shown in FIG. 4B, the semiconductor device 101 may optionally include a second conductive structure 55 disposed between the semiconductor stack 20 and the reflecting structure 60. The second conductive structure 55 can facilitate lateral current spreading (along X-axis and/or Y-axis) for currents flow in or out the semiconductor stack 20, so as to improve light emitting uniformity and efficiency of the semiconductor device 101. In this embodiment, the second conductive structure 55 contacts a lower surface of the first semiconductor structure 21 and an upper surface of the reflecting structure 60. The second conductive structure 55 may contact the entirely lower surface or a part of the lower surface of the first semiconductor structure 21. The second conductive structure 55 may be transparent for the light emitted from the active structure 23. In some embodiments, the second conductive structure 55 has a transmittance over 80% for the light emitted from the active structure 23. In some embodiments, the second conductive structure 55 may have a thickness in a range of 50 nm to 600 nm.

Furthermore, the semiconductor device 101 may optionally include a protecting layer 80. As shown in FIG. 4B, the protecting layer 80 covers the second semiconductor structure 22 and the first electrode structure 30 to prevent the semiconductor stack 20 from damages or decays caused by environmental affection. The protecting layer 80 includes an opening 81 to expose the pad portion 31 for external wires connecting thereto. In some embodiments, the protecting layer 80 may have a transmittance for the light emitted from the active structure 23, and the transmittance is over 80%. The positions, relative relationships, and material of other layers or structures as well as structural variations in the semiconductor device 101 are described in detail in previous embodiments, and are not repeatedly described herein.

FIG. 4C shows a cross-sectional view of the semiconductor device 102 in one embodiment in accordance with the present disclosure. The semiconductor device 102 is similar to the semiconductor device 101, and can further include an insulating structure 90 between the semiconductor stack 20 and the second conductive structure 55. The insulating layer 90 can be patterned to control distribution of the current flow in or out the semiconductor stack 20. In one embodiment, the insulation structure 90 is overlapped with the extending portions 32 of the first electrode structure 30 in the vertical direction (along Z-axis), so that current distribution within the semiconductor stack 20 can be more uniform and reduce the light blocking effect of the first electrode structure 30. In one embodiment, the insulating structure 90 is not overlapped with the pad portion 31 in the vertical direction (along Z-axis) to enhance reliability. In one embodiment, the insulating structure 90 can further include a plurality of holes (not shown) which are not overlapped with the first electrode structure 30 in the vertical direction (along Z-axis), and the second conductive structure 55 can connect the second semiconductor structure 22 through the plurality of holes. Thus, current spreading within the semiconductor stack 20 can be precisely controlled by arrangement of the plurality of holes.

The insulating structure 90 may be transparent for the light emitted from the active structure 23. In some embodiments, the insulating structure 90 has a transmittance over 80% for the light emitted from the active structure 23. The insulating structure 90 can have a thickness between 20 nm to 180 nm. In some embodiment, the thickness of the insulating structure 90 is smaller than a thickness of the second conductive structure 55. The positions, relative relationships, and materials of other layers or structures as well as structural variations in the semiconductor device 102 are described in detail in previous embodiments, and are not repeatedly described herein.

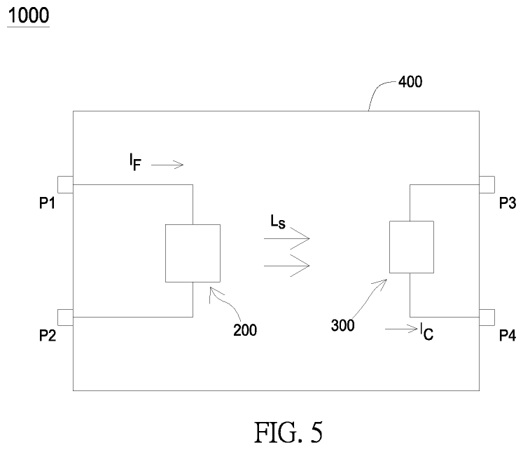

FIG. 5 shows a schematic view of a transmission module 1000 in accordance with one embodiment of the present disclosure. The transmission module 1000 includes a light emitter 200, a light receiver 300 and an encapsulation structure 400 encapsulating the light emitter 200 and the light receiver 300. The encapsulation structure 400 includes multiple contacts P1, P2, P3, P4. The light emitter 200 and the light receiver 300 are disposed in the encapsulation structure 400 and physically separated from each other without electrical connection within the encapsulation structure 400. In this embodiment, the light emitter 200 is the semiconductor device 100. In other embodiment, the light emitter 200 can be the semiconductor device 100′, 101, 102, and connects an external power source (not shown) or other components (not shown) through the contacts P1, P2. The light receiver 300 can be a photodiode or phototransistor, and connects another external power source (not shown) or other components (not shown) through the contacts P3, P4. The light emitter 200 receives the input current (I_{F}) to emit a signal light (L_{S}), and the light receiver 300 absorbs the signal light (L_{S}) to output an output current (I_{C}). In other words, the transmission module 1000 can be inputted the input current (I_{F}) to output the output current (I_{C}). The signal light (L_{S}) of the light emitter 200 is the light emitted from the active structure 23 as mentioned above, and the signal light (L_{S}) also has the peak wavelength. When the input current (I_{F}) increases, the power of the light emitter 200 increases, i.e., the amount of the signal light (L_{S}) emitted from the light emitter 200 increases. Thus, as more signal light (L_{S}) is transmitted and absorbed by the light receiver 300, the output current (I_{C}) increases. The transmission module 1000 may have a converting ratio defined as the output current (I_{C}) to the input current (I_{F}). For some applications of the transmission module 1000, such as photocoupler, the output current (I_{C}) is required to be proportional to the input current (I_{F}) as the input current (I_{F}) changes. In other words, at different input current (I_{F}), the converting ratio of the transmission module 1000 needs to keep as stable as possible.

The light receiver 300 has a photoelectric conversion efficiency for converting the signal light (L_{S}) to the output current (I_{C}). In one embodiment, the light receiver 300 can have an absorption wavelength (Wa) at which the light receiver 300 has the largest photoelectric conversion efficiency. For the signal light (L_{S}) with the peak wavelength larger than the absorption wavelength (Wa), the photoelectric conversion efficiency of the light receiver 300 decreases as the peak wavelength of the signal light (L_{S}) increases, which indicates the output current (I_{C}) also decreases as the peak wavelength of the signal light (L_{S}) increases. On the other hand, when the peak wavelength of the signal light (L_{S}) is larger than the absorption wavelength (Wa), the photoelectric conversion efficiency of the light receiver 300 and the output current (I_{C}) increase as the peak wavelength of the signal light (L_{S}) decreases.

As shown in FIG. 2, as the input current (I_{F}) increases, the deviation coefficient decreases at the operated current (the third current I3) larger than the reference current (the first current I1), which indicates the increasing degree of the power outputted by the light emitter 200 is less than the increasing degree of the input current (I_{F}). As such, at the operated current larger than the reference current, the increasing degree of the output current (I_{C}) from the light receiver 30 is declined. In addition, as shown in FIG. 3 and aforesaid above, as the input current (I_{F}) increases, the peak wavelength of the signal light (L_{S}) decreases and the photoelectric conversion efficiency of the light receiver 300 increase, which raises the increasing degree of the output current (I_{C}) of the light receiver 30 and compensate the decline of the output current (I_{C}). Therefore, the increasing degree of the output current (I_{C}) of the light receiver 300 is consistent with the increasing degree of the input current (I_{F}), and the converting ratio of the transmission module 1000 maintains substantially constant.

For all the embodiments mentioned above, the base 10 can be electrically conductive materials, including metal, semiconductor, or transparent conductive material. The metal can be Cu, Al, Cr, Sn, Au, Ni, Ti, Pt, Pb, Zn, Cd, Sb, Co, or the alloy including the aforementioned materials. The semiconductor can be IV group or III-V group semiconductors which can be Si, Ge, SiC, GaN, GaP, GaAs, AsGaP, ZnSe or InP. The transparent conductive material can include oxide or graphene. The oxide can be indium tin oxide (ITO), InO, SnO, cadmium tin oxide (CTO), antimony tin oxide (ATO), Al-doped ZnO (AZO), zinc tin oxide (ZTO), Ga-doped ZnO (GZO), indium tungsten oxide (IWO), or indium zinc oxide (IZO).

For all the embodiments mentioned above, the first semiconductor structure 21, the second semiconductor structure 22, the active structure 23 and the first contact layer 24 can include III-IV compound semiconductor materials, such as GaAs, InGaAs, AlGaAs, AlInGaAs, GaP, InGaP, AlInP, AlGalnP, AlAsSb, InGaAsP, AlGaAsP.

For all the embodiments mentioned above, the first electrode structure 30 and the second electrode structure 40 can include metal oxides, metals or alloys. For example, the metal oxides can include but not limited to ITO, InO, SnO, CTO, ATO, AZO, ZTO, GZO, ICO, IWO, ITIO, ZnO, IZO, IGO or GAZO. The metals can include but not limited to Ge, Be, Zn, Ti, Al, Ni, Au, Pt, Sn or Cu. The alloys can include two or more of the material selected from the abovementioned metals, such as GeAuNi, BeAu, GeAu or ZnAu.

For all the embodiments mentioned above, the first conductive structure 50 and the second conductive structure 55 can include transparent conductive materials, such as ITO, InO, SnO, CTO, ATO, AZO, ZTO, GZO, IWO, ZnO, MgO, or IZO.

For all the embodiments mentioned above, the reflecting structure 60 can include metals or alloys, such as Cu, Al, Sn, Au, Ag, Pb, Ti, Ni, Pt, W, or the alloys which include the aforementioned metal materials.

For all the embodiments mentioned above, the bonding structure 70 can include transparent conductive materials, metals, and alloys. The transparent conductive materials can include but is not limited to ITO, InO, SnO, CTO, ATO, AZO, ZTO, GZO, GaP, ICO, IWO, ITIO, IZO, IGO, GAZO, graphene or the combination of the above materials. The metals can include but is not limited to Cu, Al, Sn, Au, Ag, Pb, Ti, Ni, Pt, and W. The alloys can include two or more of the material selected from the above-mentioned metal.

For all the embodiments mentioned above, the protecting layer 80 can include insulating materials, such as TaOx, AlOx, SiOₓ, TiOₓ, SiNₓ, SiOₓN_{y}, Nb₂O₅ or spin-on glass (SOG).

For all the embodiments mentioned above, the insulating structure 90 can include insulating materials, such as oxide or fluoride. The oxide is, for example, silicon dioxide (SiOx), and the fluoride is, for example, magnesium fluoride (MgFx).

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a base; and
a semiconductor stack including a first semiconductor structure located on the base, a second semiconductor structure located on the first semiconductor structure, and an active structure located between the first semiconductor structure and the second semiconductor structure, the active structure including two confinement layers and a well layer located between the two confinement layers:
wherein one of the two confinement layers includes Alₓ₁Ga₁₋ₓ₁As, and x1 is equal to or larger than 0.25 and equal to or smaller than 0.4;
wherein the well layer includes Inₓ₂Ga₁₋ₓ₂As, and x2 is equal to or larger than 0.25 and equal to or smaller than 0.3;
wherein the one of the two confinement layers have a first thickness in a range of 200 nm to 400 nm, and the well layer has a second thickness in a range of 3 nm to 6 nm.

2. The semiconductor device according to claim 1, wherein the active layer outputs a first power and emits a first light having a first peak wavelength at a first current, and outputs a second power and emits a second light having a second peak wavelength at a second current, and outputs a third power and emits a third light having a third peak wavelength at a third current:
wherein the first current, the second current and the third current are different from each other, and the first peak wavelength, the second peak wavelength and the third peak wavelength are different from each other.

3. The semiconductor device according to claim 2, wherein the first current, the second current and the third current are smaller than 50 mA.

4. The semiconductor device according to claim 2, wherein the second current is smaller than the first current, and the third current is larger than the first current.

5. The semiconductor device according to claim 4, wherein the semiconductor device has a first deviation coefficient at the second current and a second deviation coefficient at the third current, wherein the first deviation coefficient is a first power ratio of the second power to the first power divided by a first current ratio of the second current to the first current and the second deviation coefficient is a second power ratio of the third power to the first power divided by a second current ratio of the third current to the first current, and wherein the first deviation coefficient is larger than the second deviation coefficient.

6. The semiconductor device according to claim 5, wherein the first deviation coefficient and the second deviation coefficient are in a range of 0.85 to 1.1.

7. The semiconductor device according to claim 4, wherein the second current is smaller than 1 mA and equal to or larger than 0.1 mA, and the third current is larger than 1 mA and equal to or smaller than 10 mA.

8. The semiconductor device according to claim 2, wherein the first peak wavelength is smaller than the second peak wavelength and larger than the third peak wavelength.

9. The semiconductor device according to claim 2, wherein the first peak wavelength, the second peak wavelength and the third peak wavelength are in a range of 850 nm to 1150 nm.

10. The semiconductor device according to claim 1, further comprising a reflecting structure located between the base and the first semiconductor structure.

11. The semiconductor device according to claim 10, further comprising a conductive structure disposed between the reflecting structure and the first semiconductor structure.

12. The semiconductor device according to claim 1, further comprising a first electrode structure disposed on the second semiconductor structure.

13. The semiconductor device according to claim 12, further comprising a contact layer disposed between the first electrode structure and the second semiconductor structure.

14. The semiconductor device according to claim 12, wherein the contact layer includes a contact area covered by the first electrode structure and an exposing area uncovered by the first electrode structure.

15. The semiconductor device according to claim 1, wherein the well layer directly contacts the two confinement layers.

16. The semiconductor device according to claim 1, wherein the active structure includes multiple barrier layers located between the well layer and the two confinement layers, and one of the barrier layers include Alₓ₃Ga₁₋ₓ₃AS_{y}P_{1-y}, and x3 is equal to or larger than 0.25 and equal to or smaller than 0.35, y is equal to or larger than 0.15 and equal to or smaller than 0.25.

17. The semiconductor device according to claim 16, wherein a thickness of the one of the barrier layers is in a range of 3 nm to 6 nm.

18. The semiconductor device according to claim 16, wherein the active structure includes multiple well layers, and each of the well layers is sandwiched by the barrier layers.

19. A transmission module, comprising,
a semiconductor device of claim 1 emitting a signal light with a peak wavelength at an input current, and
a light receiver receiving the signal light to output an output current;
wherein the output current is proportional to the input current.

20. The transmission module according to claim 19, wherein the light receiver has an absorption wavelength, and the peak wavelength is larger than the absorption wavelength.
